(19) United States
(12) Patent Application Publication
(10) Pub. No.: US 2026/0254264 A1
(43) Pub. Date: Aug. 27, 2026

(54) METHOD FOR CHARACTERISING AND/OR OPTIMISING AT LEAST ONE ENERGY STORAGE MODULE

(71) Applicant: PULSETRAIN GMBH, Karlshuld (DE)

(72) Inventors: Manuel Kuder, München (DE); Florian Schwitzgebel, Neubiberg (DE)

(21) Appl. No.: 18/854,424

(22) PCT Filed: Apr. 17, 2023
(86) PCT No.: PCT/EP2023/059932

§ 371 Date: Oct. 4, 2024

(30) Foreign Application Priority Data
Apr. 28, 2022 (DE) 10 2022 110 426.5

(51) Int. Cl. H02J 7/50; G01R 31/385; G01R 31/389; H02J 7/34

(52) U.S. Cl. CPC H02J 7/575; G01R 31/385; G01R 31/389; H02J 7/34; H02J 2207/20

(57) ABSTRACT

The invention relates to a method for characterizing and/or optimizing at least one energy storage module using a multilevel converter system, in which a multiplicity of energy storage modules and transistors are provided, each energy storage module being able to be connected in parallel and/or in series with the respective adjacent energy storage module, and the energy storage modules, preferably the transistors, are switched in such a way that at least one energy storage module is characterized and/or optimized on the basis of a, preferably current-independent, frequency response.

The invention relates to a method for characterizing and/or optimizing at least one energy storage module, in which a multiplicity of energy storage modules and transistors are provided.

Energy stores to date are usually loaded with DC voltage (DC). This is due to the design of conventional converter systems. Attempts are made to keep the AC voltage components, that is to say harmonic oscillations, away from the energy stores.

Since many energy stores need to be connected in series or parallel under these circumstances, a battery management system (BMS) is necessary. The energy stores may have e.g. a DC link capacitor connected downstream of them. This is used to smooth the three-phase currents of the converter further and to keep high-frequency oscillations away from the energy stores and also to intercept switching overshoots, as the inductance of the energy stores would continue to drive the current. The aim of this approach is to load the energy stores with DC, as it is assumed that this contributes to the stability of the battery cell and reduces losses.

In a conventional electric vehicle, for example, the converters that transfer the energy to the electric motor and deliver it to the battery again during braking energy recovery (recuperation) may be provided on the DC bus. Chargers that can operate with AC voltage (AC) or DC voltage (DC) can also be connected to this bus, for example.

These converters are usually in the form of two-level converters, e.g. in the form of a B6 bridge in the case of a three-phase design, or—particularly in the field of solar installations—in the form of three-level converters.

As an alternative to bridge circuits as converters, so-called multilevel converter systems (MMC systems) are known.

By way of example, the energy stores or energy sources used can be batteries, e.g. rechargeable batteries, capacitors, fuel cells and/or solar installations. The energy stores in this case are not hardwired to one another, but rather are combined as individual submodules. This design is required for each phase. The energy stores are therefore divided among these phases and can be permanently connected up in series or parallel, for example.

Previous methods for characterizing energy stores or energy sources have commonly been imprecise. Moreover, energy stores or energy sources that are e.g. frequency-dependent often result in losses.

It is therefore an object of the invention to provide a method that permits precise characterization of at least one energy storage module and/or reduces losses.

This object is achieved by way of the method having the features of claim 1.

According to the invention, the method is designed to characterize and/or optimize at least one energy storage module using a multilevel converter system, preferably a modular multilevel battery system (B2M), or can be used for this purpose.

The optimization is preferably carried out with regard to low losses.

The losses P depend on the real part of the impedance Z according to P=I²*Z.

The energy storage module may be a storage means of a, preferably frequency-dependent, electrical source, for example a battery, e.g. a rechargeable battery, a fuel cell, a solar cell and/or a (super) capacitor.

By way of example, the method can be used in electric vehicles, e.g. electric cars, electric trucks and/or electric buses. Use in hydrogen vehicles is also conceivable too. Furthermore, said method can be applied to stationary energy stores and/or other converter systems that are used on the power grid and/or operated by an AC motor.

A multiplicity of energy storage modules and transistors are provided.

A, preferably modular, multilevel converter system describes a type of arrangement, or circuit, of multiple energy storage modules and transistors.

Each energy storage module can have at least one or precisely one battery, e.g. a rechargeable battery, and/or at least one or precisely one capacitor.

By way of example, the transistors are used as switches that can be used to select e.g. current and/or voltage paths. This allows the energy storage modules to be incorporated into or from excluded a desired configuration, for example.

Preferably, each energy storage module has at least or precisely two, three, four, five, six, seven, eight, nine, ten or more associated transistors.

The transistor may be designed for a voltage of less than 500 V, 400 V, 300 V, 200 V, 100 V, 50 V, 40 V, 30 V, 20 V or 10 V, for example. Preferably, the transistor may be designed for a voltage of between 2 V and 8 V, e.g. 3 V, 4 V, 5 V, 6 V or 7 V.

Each energy storage module can be connected in parallel and/or in series with the respective adjacent energy storage module. Preferably, each energy storage module can be connected in series with the respective adjacent energy storage module. The option of connection in parallel is advantageous but not necessary.

Preferably, the adjacent energy storage modules are connected to one another via two current and/or voltage paths in each case. Each path can have an associated transistor.

By way of example, there is provision for three transistors between two adjacent energy storage modules. The energy storage modules can therefore be connected e.g. in parallel or in series.

Multilevel converter systems are much more versatile compared with bridge circuits. As such, almost any configurations can be produced. By way of example, the energy storage modules can be connected arbitrarily, e.g. in parallel or in series, in relation to one another. Single energy storage modules can also be incorporated into or excluded from a desired configuration.

The energy storage modules, preferably the transistors, are switched in such a way that at least one energy storage module is characterized and/or optimized on the basis of a, preferably current-independent, frequency response.

Characterization can be accomplished e.g. by connecting, or impressing, a current pulse to, or onto, the energy storage module and measuring the resultant voltage response.

Alternatively or additionally, so-called electrochemical impedance spectroscopy (EIS) involves the response of a system being examined under AC loading. Each system to be examined can basically be understood as a combination of resistances, capacitances and/or inductances that correspond to specific real components of processes. Precise knowledge of the system permits an equivalent circuit diagram to be produced. Changes in the electrical response can therefore be interpreted as changes in individual system components.

In most cases, the electrical resistance is frequency-dependent, however. Current and voltage are not in phase, i.e. the voltage and current curves are offset from one another in time. This response is exhibited by all energy storage systems, e.g. (super) capacitors, batteries, fuel cells.

An (ideal) capacitor is a typical example of this. Given DC current and at very low AC frequencies, the resistance of said capacitor is high, and so no or only a very low current flows. At higher frequencies, the resistance becomes increasingly lower. The current that flows and the voltage are—in the case of an ideal capacitor—90° out of phase, however.

In real systems, capacitors can be found in the form of nonconductive surface layers and/or air gaps, for example. An electrochemical double layer produced at the interface between a metal and an electrolyte is also a capacitor.

An inductance, e.g. a coil, exhibits precisely the opposite response to a capacitor. Here too, the phase shift between current and voltage is 90°, but with a different arithmetic sign. An inductance has an extremely high resistance at high frequencies, whereas said resistance is approximately zero at low frequencies or for DC current. In the technical systems under consideration here, inductances are therefore significant only at high frequencies. By way of example, the lines and (unintentional) cable loops can act as an inductance. This should preferably be taken into account in the measurement arrangement for impedance spectroscopy.

Other frequency-dependent phenomena are diffusion processes of a battery, for example. These are represented by a so-called Warburg impedance. Less than ideal capacitive response, for example caused by a porous and/or rough surface, can be described by an element with constant phase rather than by a capacitor.

When the frequency response of the energy storage module has been characterized, it can be used—if the state of charge is known and/or estimated—to assess the aging and/or temperature of the energy storage module, for example.

The frequency response of the energy storage module is effectively used as a basis for deducing further characteristics of the energy storage module.

It was surprising that switching the energy storage modules, preferably the transistors, allows the frequency response to be ascertained. The frequency, e.g. the switching frequency, is independent of the current. Only the voltage can influence it—e.g. by way of the different switching patterns.

Furthermore, it has been found that the losses from an energy storage module are dependent on the frequency, e.g. the switching frequency, at which the energy storage module is operated.

An energy storage module can therefore be operated at a specific switching frequency in order to reduce losses.

The multilevel converter system can preferably be operated in a frequency range that is ideal for the energy storage module. This frequency range can change over the life or the state of charge.

By way of example, an energy storage module can be connected and/or disconnected at a predefined frequency.

The optimization is preferably dependent only on the frequency and not on the current.

The frequency, e.g. the switching frequency (typically above the fundamental harmonic of, for example, 50 Hz) can preferably be shifted to a frequency range in which the losses from the energy storage module are lowest. This allows e.g. the total battery losses of a vehicle to be diminished.

An optimized frequency can preferably be between 1 kHz and 4 kHz. The Joule losses from the energy storage modules are low in this range.

To optimize an energy storage module in respect of losses, it can be connected as appropriate, e.g. in parallel or in series with one or more energy storage modules.

The switching can preferably be carried out in a pulse-width-modulated (PWM) manner.

At least one transistor, preferably all transistors, has/have a switching frequency of at least 1 Hz, 2 Hz, 3 Hz, 4 Hz, 5 Hz, 6 Hz, 7 Hz, 8 Hz, 9 Hz, 10 Hz, 15 Hz, 20 Hz, 30 Hz, 40 Hz, 50 Hz or 100 Hz.

A converter section can have 100 levels, for example. The entire converter section can therefore exhibit 100 times the frequency.

By way of example, the maximum switching frequency of a transistor and/or of the entire converter section may be at least 50 kHz, 60 kHz, 70 kHz, 80 kHz, 90 kHz, 100 kHz, 150 kHz, 200 kHz, 250 kHz, 300 kHz, 400 kHz, 500 kHz, 600 kHz, 700 kHz, 800 kHz, 900 kHz, 1 MHz, 1.1 MHz, 1.2 MHz, 1.3 MHz, 1.4 MHz, 1.5 MHz, 2 MHz, 5 MHz, 10 MHz, 20 MHz, 30 MHz, 40 MHz, 50 MHz, 80 MHz, 100 MHz or 120 MHz.

By way of example, the transistor may be in the form of a metal oxide semiconductor field effect transistor (MOSFET) or can comprise a MOSFET.

MOSFETs can be switched at high frequencies.

The semiconductor material provided may be silicon, gallium nitride, gallium arsenide and/or silicon carbide, for example. Organic semiconductors are also conceivable in principle.

By way of example, preconditioning and/or the setting of an operating optimum is possible for MOSFETs.

Developments of the invention can also be found in the dependent claims, the description and the accompanying drawings.

According to one embodiment, the energy storage module is in the form of a battery, preferably a rechargeable battery.

Preferably, the energy storage module is rechargeable. One-time energy storage modules are also conceivable in principle, however.

Preferably, the energy storage module permits longer-term storage of energy than e.g. a capacitor.

According to another embodiment, the energy storage module to be characterized is incorporated into a configuration.

By way of example, an energy storage module for characterization may initially not be incorporated in a configuration. It can subsequently be incorporated into a configuration and for example connected in series with at least one further energy storage module. This leads from a flow of current of 0 A to one of >0 A, in the characteristic of which the voltage response is measured. The ratio of voltage and current yields the complex resistance. Knowledge of the frequencies can be taken as a basis for e.g. providing the equivalent circuit diagram with data.

The option of connecting the energy storage modules in series with another is one sufficient for characterization. Connection in parallel is therefore not necessary, but fundamentally conceivable if the energy storage modules have corresponding paths. Furthermore, this increases the degrees of freedom relating to data collection. As such, the points can likewise be recorded with different currents, for example.

This allows the frequency response to be ascertained.

One-time incorporation into a configuration is sufficient in this case to obtain a first measurement point. With regard to more precise measurement, on the other hand, it is advantageous to perform multiple measurements. The (re) configuration can remain the same, for example. First 0 A and then-possibly repeatedly-a value (or different values)>0 A can be chosen, for example.

According to another embodiment, the configuration is varied.

A change of configuration allows different measurement points to be determined. By way of example, an energy storage module can be connected first in series and then in parallel.

As such, the frequency response for different configurations can be determined.

Preferably, the configuration can change at each level. Alternatively or additionally, a change of configuration can be carried out within a level.

The energy storage modules can be incorporated into or excluded from a desired configuration.

Exclusion can be carried out for example by closing a, e.g. upper, switch so that no current flows through the applicable energy storage module.

According to another embodiment, a current pulse is connected to, or impressed onto, the energy storage module and the resultant voltage response is measured.

During this, the multilevel converter system can produce a sinusoid on the load, e.g. a motor or a current source, e.g. a power grid.

Measurement of the voltage response allows pulse characterization to be carried out.

A portion can be removed from the sinusoidal characteristic of the current or voltage curve for example by way of a change of configuration, e.g. incorporation into a configuration, connection in series and/or parallel. Depending on the switching frequency and the sinusoidal frequency, this can result in a current that is constant in this time step, for example. Preferably, this method also works when the pulse is not constant.

The real part of the impedance Z depends on the voltage and the current according to Z=u/i.

The real part of the impedance is different depending on the frequency range. The voltage response can therefore be taken as a basis for ascertaining the frequency response.

The frequency response can be ascertained without the need for connection in parallel. In the case of a vehicle, it is also possible to characterize one, more or all energy storage modules while the vehicle is in motion, i.e. it is not necessary for the vehicle to be at a standstill.

According to another embodiment, the duration of the current pulse is varied.

The frequencies that are intended to be examined determine how long the current pulse needs to be, for example.

Varying the duration of the current pulse allows further measurement points to be determined in order to ascertain the frequency response.

According to another embodiment, an energy storage module to be optimized is incorporated into a configuration in such a way that the real part of the impedance is low and/or the frequency is high.

In ranges containing high frequencies, the real part of the impedance is high, whereas it is lower in ranges containing midrange frequencies. An optimized energy storage module is therefore preferably operated in a range containing high frequencies and therefore with a low impedance.

By way of example, an energy storage module for optimization can be connected in parallel or in series with at least one further energy storage module.

The configuration can remain the same at each level and/or within a level.

Alternatively, the configuration can change at each level and/or within a level.

A configuration can merely contain the energy storage module to be optimized. Alternatively, a configuration can also have at least one further energy storage module. Preferably, each configuration has a multiplicity of energy storage modules that are connected in parallel and/or in series with one another.

By way of example, a change of configuration allows the frequency to be set.

If it is known that an energy storage module has the lowest losses at 20 Hz, for example, a (re) configuration with the frequency 20 Hz can be selected.

According to another embodiment, a characterization according to the invention is performed before the optimization.

In this way, the frequency response of the energy storage module can first be ascertained.

Alternatively, it is also possible to use existing data. By way of example, the data can comprise the frequency response of comparable energy storage modules, simulations and/or historical data relating to the energy storage module.

Once the frequency response is known, the energy storage module can be operated in a range in which losses are low. The energy storage module is therefore switched to a specific configuration.

According to another embodiment, the optimization is carried out in respect of a single energy storage module.

The energy storage module to be optimized is therefore incorporated into a configuration in such a way that the losses from the energy storage module to be optimized are as low as possible.

This can be achieved in a technically comparatively simple way, since it is not necessary to consider the other energy storage modules. However, it can lead to higher losses for the other energy storage modules.

According to another embodiment, the optimization is carried out in respect of multiple, preferably all, energy storage modules.

By way of example, two, three, four, five or more energy storage modules can be optimized.

Preferably, the optimization is carried out in respect of all energy storage modules.

This leads to losses as a whole being reduced.

To find one or more configurations in which an optimization is carried out in respect of the total loss from multiple or all energy storage modules, software can be used.

By way of example, the software can operate using neural networks, Kalman filters and/or artificial intelligence. By way of example, the method can therefore be constantly improved further using recorded data.

The invention also relates to a multilevel converter system, preferably a modular multilevel battery system, for carrying out the method according to the invention, having a multiplicity of energy storage modules and transistors, each energy storage module being connected in parallel and/or in series with the respective adjacent energy storage module.

The system comprises a control apparatus that is designed to switch the energy storage modules, preferably the transistors, in such a way that at least one energy storage module is characterized and/or optimized.

At least one transistor has a switching frequency of at least 1 Hz.

An optimized frequency can preferably be between 1 kHz and 4 kHz.

All embodiments and components of the multilevel converter system that are described here are preferably designed to be operated, e.g. by means of a control apparatus, according to the method described here. Furthermore, all embodiments of the apparatus that are described here and all embodiments of the method that are described here can each be combined with one another, preferably also in a manner detached from the specific form in connection with which they are mentioned.

The invention is described by way of illustration below with reference to the drawings, in which:

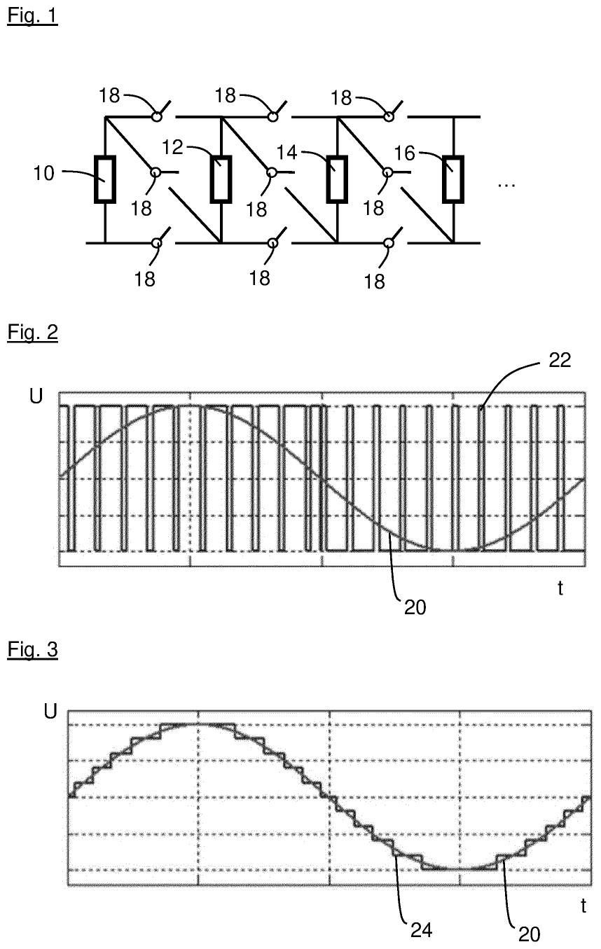

FIG. 1 shows an embodiment of an MMC system according to the invention,

FIG. 2 shows a characteristic of the output voltage of a PWM system according to the prior art,

FIG. 3 shows a characteristic of the output voltage of an embodiment of an MMC system according to the invention,

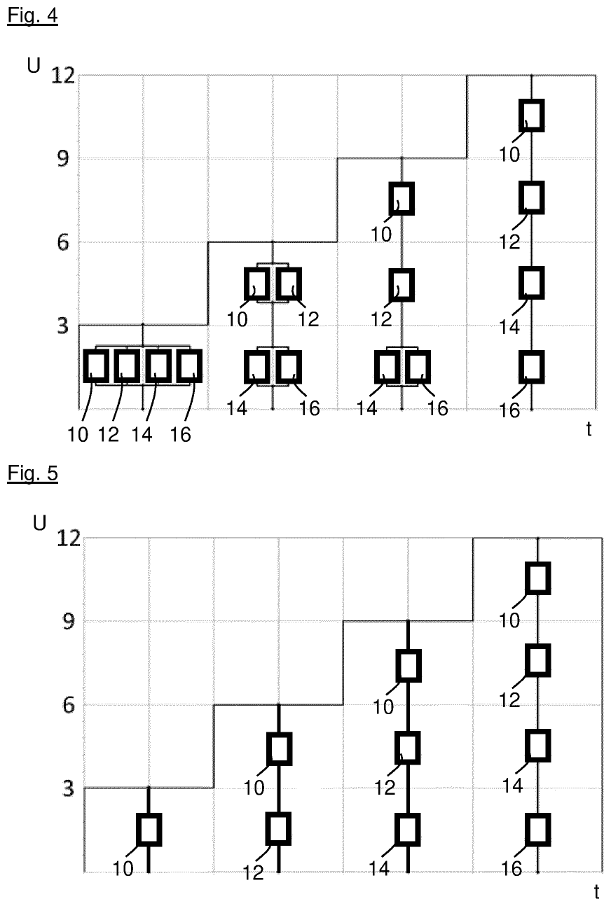

FIG. 4 shows a power (loss)-optimized configuration of an MMC system according to the prior art,

FIG. 5 shows a configuration of an embodiment of an MMC system according to the invention for characterizing and/or optimizing energy storage modules,

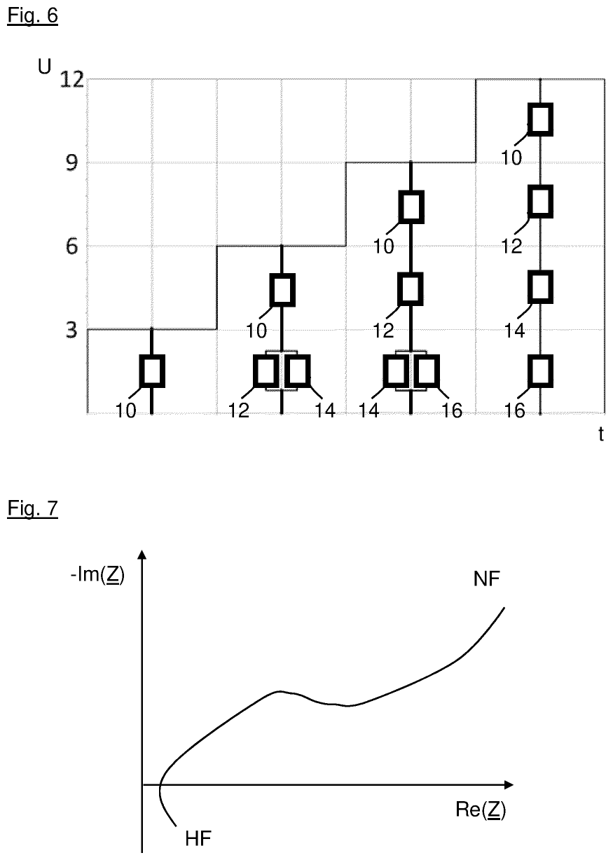

FIG. 6 shows a configuration of a further embodiment of an MMC system according to the invention for characterizing and/or optimizing energy storage modules,

FIG. 7 shows a Nyquist graph of an electrochemical impedance spectroscopy,

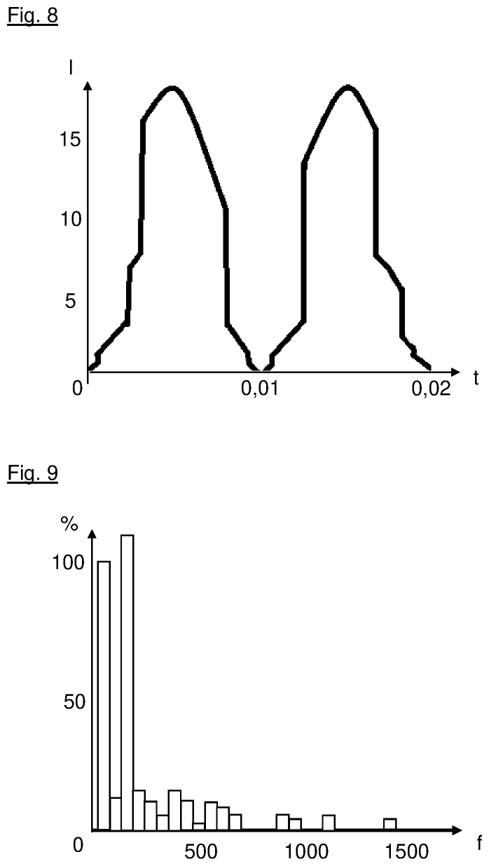

FIG. 8 shows a graph of current loading against time for energy storage modules connected in parallel, and

FIG. 9 shows a graph of the frequency components.

It should first of all be noted that the embodiments shown are of a purely illustrative nature. Individual features can thus be implemented not only in the combination shown but also alone or in other technically meaningful combinations. For example, the features of one embodiment can be combined in any desired manner with features of another embodiment. The configuration and/or number of energy storage modules, paths and transistors shown is purely illustrative and fundamentally arbitrary.

If a figure contains a reference sign that is not explained in the directly related text of the description, reference is made to the corresponding preceding or subsequent comments in the description of the figures. The same reference signs are thus used for identical or comparable components in the figures and are not explained again.

FIG. 1 shows a multilevel converter system for characterizing and/or optimizing at least one energy storage module 10, 12, 14, 16.

Adjacent energy storage modules 10, 12, 14, 16 are connected to one another via multiple paths in each case.

Each path contains a switch in the form of a transistor 18.

The adjacent energy storage modules 10, 12, 14, 16 can therefore be connected in series or parallel with one another. Individual energy storage modules 10, 12, 14, 16 can also be bypassed when required, e.g. by closing the upper switch 18, and in this way excluded from a configuration.

FIG. 2 shows the voltage characteristic U against time t of a PWM modulation.

A three-phase DC/AC system coupling requires six switches in this case.

In the case of a B6 bridge or a two-level converter, the DC voltage is synchronously switched on by way of multiple switches or one switch, resulting in an AC voltage only on average over time.

The sinusoidal target voltage 20 is therefore only rudimentarily recreated by the output voltage 22 of the PWM system.

FIG. 3 shows the voltage characteristic U in volts against time t in seconds of an MMC system.

The sinusoidal target voltage 20 is emulated by setting up individual levels 24. The output voltage 24 therefore emulates the sinusoidal target voltage 20 in a considerably improved manner.

FIG. 4 shows a power (loss)-optimized configuration of an MMC system. The voltage U in volts is represented against time t in seconds.

By way of illustration, it is shown how the first three voltage levels can be formed by connecting the energy storage modules 10, 12, 14, 16 in parallel.

To optimize the power and obtain the best efficiency, all of the energy storage modules 10, 12, 14, 16 at each level are always incorporated into the configuration.

By contrast, FIG. 5 shows a configuration in which all of the energy storage modules 10, 12, 14, 16 are connected in series.

Such a configuration can be used to characterize the energy storage module 10.

In this example, the energy storage module 10 is always incorporated, and so a respective measured value for different levels can be determined.

As a result of the energy storage module 10 being incorporated in the configuration on its own at the first level and being connected in series with one further energy storage module 12 at the second level, with two further energy storage modules 12, 14 at the third level and with three further energy storage modules 12, 14, 16 at the fourth level, the response in different frequency ranges can be ascertained.

The configuration shown in FIG. 5 can therefore be used to characterize the energy storage module 10.

Alternatively or additionally, the configuration shown in FIG. 5 may also be an optimized configuration in which the losses for one or more energy storage modules 10, 12, 14, 16 are low.

FIG. 6 depicts a further, illustrative configuration.

The energy storage module 10 is on its own at the first level and connected in series with at least one of the other energy storage modules 12, 14, 16 at the other levels.

The configuration shown in FIG. 6 may be an optimized configuration in which the losses for one or more energy storage modules 10, 12, 14, 16 are low.

The configurations depicted in FIGS. 5 and 6 are purely illustrative. Depending on which energy storage module(s) 10, 12, 14, 16 is/are intended to be characterized and/or optimized with regard to losses, other configurations are also conceivable.

FIG. 7 shows a Nyquist graph of an electrochemical impedance spectroscopy (EIS) using the example of a lithium ion battery as energy storage module 10, 12, 14, 16.

The approach can be used for other storage technologies mutatis mutandis.

The EIS of battery cells is very different depending on the manufacturer, but the cells of one manufacturer also differ greatly from one another on account of different protective circuitry, cathode and anode materials and/or electrolytes. It is of particular interest that the EISs differ from one another even in the case of cells of the same type of construction and from the same manufacturer. The basic characteristic is the same for all types of storage means, however.

The x-axis represents the real part of the impedance, that is to say of the complex impedance in Q. This corresponds to the actual losses from the battery at the respective operating points.

Moreover, the y-axis shows the imaginary part of the impedance in Q at the respective operating points.

The different operating points arise as a result of different voltage frequencies applied to the battery. As such, the frequencies in the upper right-hand range are low frequencies NF and are greatly influenced by diffusion. The losses in the lower left-hand range correspond to losses at high frequencies HF and are greatly influenced by inductive response.

The Nyquist graph does not afford the opportunity to directly read off exact frequency values. These need to be shown separately.

However, the Nyquist graph reveals that the point having the lowest losses (P=I²*Re(Z)) is dependent on the x-axis and is the point that is furthest left, as only the resistive losses arise here.

Conventional loading with DC in the Nyquist graph can be found at the low frequencies NF and therefore at the maximum losses.

Measurements were also performed with different states of charge (not shown). This resulted in different curve characteristics.

The losses from the battery are therefore dependent not only on the frequencies and the current but also on the state of charge of said battery. It would therefore be advantageous to align the losses for different states of the battery.

Temperature and/or state of health also influences the frequency response of, or the losses from, the battery.

In the case of the battery shown, it would therefore be desirable to load it e.g. with a frequency of approximately 2 kHz in order to operate it at the operating point having low losses. This point corresponds to the point of intersection with the x-axis.

The Nyquist graph relating to this battery shows a very homogeneous response at the point with the lowest resistances. This is not the case for all batteries, however.

These measurements can now be used to calculate a battery model, a so-called equivalent circuit diagram (ESB).

The battery can be modelled using three RC elements, the filter capacitance being chosen to be negligibly low so as not to distort the simulation. This results in parameters that reflect the frequency response of the battery.

Modellings without or with an RC element, or with two, three or more RC elements, are also possible.

High-frequency ranges above 4 kHz and ranges containing very low frequencies can be ignored in this case.

The conventional approach is questioned according to the invention, especially since DC loading of battery storage means is disadvantageous. It has been found that high-frequency sinusoidal loadings have a positive effect on the aging of the battery cells and can have a positive influence on the so-called state of health (SOH) of the batteries.

It is therefore advantageous to operate the battery at suitable operating points in order to minimize aging effects.

This is possible only with difficulty in the case of a conventional converter, however. It would require additional converters that would need to model these harmonic oscillations onto the battery, as the three-phase design of conventional converter systems results in the currents of the three phases cancelling one another out on average. An advantage of the t system according to which the reactive currents, that is to say currents that do no work, do not load the entire battery system is therefore limited.

Batteries in MMC systems can experience DC loading at low frequencies. Filtering said DC loading would certainly be conceivable, in principle, using capacitors. However, these would be disproportionately large, since they must lose barely any charge over an entire fundamental oscillation. The batteries in battery-operated MMC systems are subject to the fundamental frequency of the output current.

In the specific case of battery-operated MMC systems with connection in parallel, the current follows the principal current. This is chopped as a result of the configurations being changed, however.

Moreover, connection in parallel results in the current being split over multiple energy storage modules 10, 12, 14, 16. This leads to a smaller current in the respective energy storage modules 10, 12, 14, 16 than flows through the entire system overall. A converter type that permits this is the modular multilevel battery converter (M2B), effectively a subtype of an MMC system.

FIG. 8 shows the curve shape of the current I applied to an M2B module during a sinewave (measurement using eight M2B modules and an additional capacitor module fitted with 860 μF), against time t.

The curve shape resembles a rectified sinewave. The differences with respect to the envelope of a rectified sinusoidal signal arise as a result of the connection of the energy storage modules 10, 12, 14, 16 in parallel. Step changes in the current loading occur if previously parallel-connected energy storage modules 10, 12, 14, 16 change to series mode.

FIG. 9 shows the frequency components of the current curve shown in FIG. 8 in percent. As can be expected with a rectified sinusoidal, the frequencies f=0 Hz and f=100 Hz dominate. Other frequency components such as 50 Hz, 150 Hz, etc., are significantly lower and have an amplitude of less than 15% of the DC component.

In particular low frequencies up to approximately 300 Hz have a high relative share.

Using an MMC system or especially an M2B on the European power grid (50 Hz) leads to the batteries being loaded with 100 Hz. This corresponds to double the value, since both the positive and the negative half-cycle of a sinewave flow through the batteries.

If the converter is used on a three-phase motor, the frequency loading is therefore dependent on the electrical speed of the motor and corresponds in the converter modules to double the value of this speed.

If the losses for this illustrative battery are now lowest at 2 kHz, an MMC system operated at an output frequency of 1 kHz can lower the losses.

The variable battery interconnection of MMC systems means that the frequency range in which the energy storage modules 10, 12, 14, 16 are loaded can be freely influenced, however. This is also necessary because the optimum operating point is dependent on different parameters, and changes e.g. over the course of the life of one energy storage module 10, 12, 14, 16 (and possibly of the other energy storage modules 10, 12, 14, 16).

This can be implemented for example by way of software and/or software updates.

For example, dependencies on the temperature of the energy storage modules 10, 12, 14, 16 can also be compensated for.

Accordingly, a dependency on the number of cycles (life) of the energy storage modules 10, 12, 14, 16 can be compensated for.

The method according to the invention can preferably be repeated at intervals of time in order to take account of aging influences. In order to eliminate temperature sensors, the method can be repeated e.g. continually.

The loading frequency of the converter can preferably be adjusted for different charging and/or discharge curves.

The offset component of the load current means that it is not possible to achieve 100% of the expected optimization, since a sinusoid that has been shifted through its amplitude also has a DC component. This corresponds to 50% and an improvement cannot be achieved for this 50% using the method presented here.

To calculate the losses, electrical engineering uses the root mean square (RMS). This allows AC quantities to be converted into their DC losses, or RMSs. For a sinusoid that has been shifted through an offset, as is impressed on the energy storage module 10, 12, 14, 16 during the operation of an MMC system, the result is

$${U}_{rms} = \sqrt{{( {U}_{-} )}^{2} + {( {U}_{\sim} )}^{2}} .$$

That is to say that if a sinusoid is modelled onto a DC current, the RMS increases. This is the same across all frequencies. The energy storage module 10, 12, 14, 16 nevertheless has different losses. In the case of a sinusoid that has the same amplitude as the offset, the result is:

$${I}_{rms} = \sqrt{( {1}^{2} + {( \frac{1}{\sqrt{2}} )}^{2} )} = 1.2247 .$$

The losses can be ascertained directly using Ohm's law (P=I²*R). As frequency rises, resistive losses can be reduced.

As a comparison system at 0 Hz, a current that corresponds to the RMS of a sinusoid with an offset can be selected, specifically 1.23 A. Since the load current is predefined by the load, said load now needs to be modelled such that it is possible to operate the energy storage module 10, 12, 14, 16 at the optimum operating point. This exploits e.g. a property of the MMC systems with the possibility of connection in parallel.

The levels in said systems are produced through interconnection in parallel and/or series, as shown by way of illustration in FIGS. 4 to 6.

A four-level sinusoid can be produced, as depicted in FIG. 5, by forming configurations, with one energy storage module 10 being connected up in series at the first level, two energy storage modules 10, 12 being connected up in series at the second level, three energy storage modules 10, 12, 14 at the third level and four energy storage modules 10, 12, 14, 16 at the fourth level.

The remaining energy storage modules 10, 12, 14, 16 are used to reduce the internal resistance by way of connection in parallel.

This configuration can be kept across all levels. However, the possibility of connection in parallel means that there are now alternative representations of the levels. These can be used to model higher frequencies onto the battery current.

Thus, e.g. FIG. 6 shows that there is no alternative vector for the fourth level, since all of the energy storage modules 10, 12, 14, 16 are needed to produce the output voltage and there are no energy storage modules 10, 12, 14, 16 left.

There are a wide variety of possible configurations for the first, second and third levels, however, since the energy storage modules 10, 12, 14, 16 can be incorporated into a configuration in parallel or in series almost arbitrarily or can be excluded entirely.

The battery losses in the case of the vectors that do not use all of the energy storage modules 10, 12, 14, 16 are less than optimum, however, since the effect of connecting energy storage modules 10, 12, 14, 16 in parallel and the thus reduced battery losses is not used.

By way of example, all of the energy storage modules 10, 12, 14, 16 can be connected in parallel at the first level, and so the internal resistance—ignoring the complex components—is ¼.

Just in the case of the depicted four energy storage modules 10, 12, 14, 16 there is a conceivable large number of different configurations that permits modelling of the battery current.

A simulation has been used to show that a reduction in battery losses can be achieved through straightforward switchover.

There is e.g. the possibility here of halving the current through one energy storage module 10, 12, 14, 16 by connecting another energy storage module 10, 12, 14, 16 in parallel or of routing the full load current through the energy storage module 10, 12, 14, 16.

This is always possible when not all of the energy storage modules 10, 12, 14, 16 are needed to output the maximum voltage.

Using the example of an electric car, this is the case whenever the driver is not travelling at maximum speed or is not charging on the power grid. This limitation is insignificant, however, since it applies only to the highest level and can be integrated into the modulation scheme, as the sinusoid has the maximum amplitude only briefly even at maximum speed.

If switching back and forth between two configurations occurs, this leads to high-frequency loading of the energy storage module 10, 12, 14, 16. Switching back and forth between parallel and series changes the losses across the frequency.

### LIST OF REFERENCE SIGNS

10, 12, 14, 16 energy storage module
18 transistor
20 target voltage
22 PWM system output voltage
24 level, MMC system output voltage
U voltage
t time
Re(Z) real part of the complex resistance
Im(Z) imaginary part of the complex resistance
NF low frequencies
HF high frequencies
I current
f frequency

1. A method for characterizing and/or optimizing at least one energy storage module (10, 12, 14, 16) using a multilevel converter system, in which a multiplicity of energy storage modules (10, 12, 14, 16) and transistors (18) are provided, each energy storage module (10, 12, 14, 16) being able to be connected in parallel and/or in series with the respective adjacent energy storage module (10, 12, 14, 16), and
the energy storage modules (10, 12, 14, 16) are switched in such a way that at least one energy storage module (10, 12, 14, 16) is characterized and/or optimized on the basis of a frequency response.

2. The method as claimed in claim 1, wherein energy storage module (10, 12, 14, 16) is in the form of a battery, preferably a rechargeable battery.

3. The method as claimed in claim 1, wherein the energy storage module (10, 12, 14, 16) to be characterized is incorporated into a configuration.

4. The method as claimed in claim 3, wherein the configuration is varied.

5. The method as claimed in claim 1, wherein a current pulse is connected to the energy storage module (10, 12, 14, 16) and the resultant voltage response is measured.

6. The method as claimed in claim 5, wherein the duration of the current pulse is varied.

7. The method as claimed in claim 1, wherein an energy storage module (10, 12, 14, 16) to be optimized is incorporated into a configuration in such a way that the real part of the impedance is low and/or the frequency is high.

8. The method as claimed in claim 7, wherein the characterization is performed before the optimization.

9. The method as claimed in claim 7, wherein the optimization is carried out in respect of a single energy storage module (10, 12, 14, 16).

10. The method as claimed in claim 7, wherein the optimization is carried out in respect of multiple energy storage modules (10, 12, 14, 16).

11. the method as claimed in claim 10, wherein the optimization is carried out in respect of all energy storage modules.

12. The method as claimed in claim 1, wherein the energy storage modules are transistors.

13. The method as claimed in claim 1, wherein the frequency response is a current induced frequency response.
